(19) United States
(12) Patent Application Publication
(10) Pub. No.: US 2025/0185322 A1
(43) Pub. Date: Jun. 5, 2025

(54) SEMICONDUCTOR DEVICE AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventor: Makoto MIZUKAMI, Ibo Hyogo (JP)

(21) Appl. No.: 19/047,203

(22) Filed: Feb. 6, 2025

Related U.S. Application Data
(63) Continuation of application No. PCT/JP2024/003100, filed on Jan. 31, 2024.

(30) Foreign Application Priority Data
Aug. 23, 2023 (JP) 2023-135746

(51) Int. Cl. H10D 62/17; H10D 12/00; H10D 12/01; H10D 62/00; H10D 62/832

(52) U.S. Cl. CPC H10D 62/393; H10D 12/032; H10D 12/441; H10D 62/01; H10D 62/8325

(57) ABSTRACT

A semiconductor device includes a silicon carbide layer including an element region, a termination region surrounding the element region, a first semiconductor part including a first portion in the element region, and a second semiconductor part located on the first semiconductor part in a first direction, the second semiconductor part being adjacent to the first portion in a second direction; a gate electrode facing the second semiconductor part of the element region; a first insulating film located between the gate electrode and the silicon carbide layer; and a second insulating film located on the first portion of the first semiconductor part, the second insulating film being thicker than the first insulating film.

### CROSS-REFERENCE TO RELATED APPLICATION

This is a continuation application of International Application No. PCT/JP2024/003100, filed on Jan. 31, 2024; the entire contents of which are incorporated herein by reference. This application also claims priority to Japanese Application No. 2023-135746, filed on Aug. 23, 2023. The entire contents of which are incorporated herein by reference.

### FIELD

Embodiments described herein relate generally to a semiconductor device and a method for manufacturing a semiconductor device.

### BACKGROUND

In a semiconductor device that uses silicon carbide (SIC), a high-temperature heat treatment for providing conductivity by activating a region into which an impurity is introduced may cause a problem in which carbon desorbs, resulting in vacancies.

### BRIEF DESCRIPTION OF THE DRAWINGS

FIG. 1 is a schematic cross-sectional view of a semiconductor device of a first embodiment;

FIG. 2 is a schematic plan view of a silicon carbide layer of the semiconductor device shown in FIG. 1;

FIG. 3A to FIG. 5B are schematic cross-sectional views showing a method for manufacturing the semiconductor device of the first embodiment; and

FIG. 6 is a schematic cross-sectional view of a semiconductor device of a second embodiment.

### DETAILED DESCRIPTION

According to one embodiment, a semiconductor device includes a silicon carbide layer including an element region, a termination region surrounding the element region, a first semiconductor part including a first portion in the element region, the first semiconductor part being of a first conductivity type, and a second semiconductor part located on the first semiconductor part in a first direction, the second semiconductor part being adjacent to the first portion in a second direction orthogonal to the first direction; a gate electrode facing the second semiconductor part of the element region; a first insulating film located between the gate electrode and the silicon carbide layer; and a second insulating film located on the first portion of the first semiconductor part, the second insulating film being thicker than the first insulating film.

Exemplary embodiments will now be described with reference to the drawings. Similar components in the drawings are marked with like reference numerals. According to embodiments below, a first conductivity type is described as an n-type, and a second conductivity type is described as a p-type; however, the first conductivity type may be the p-type, and the second conductivity type may be the n-type.

### First Embodiment

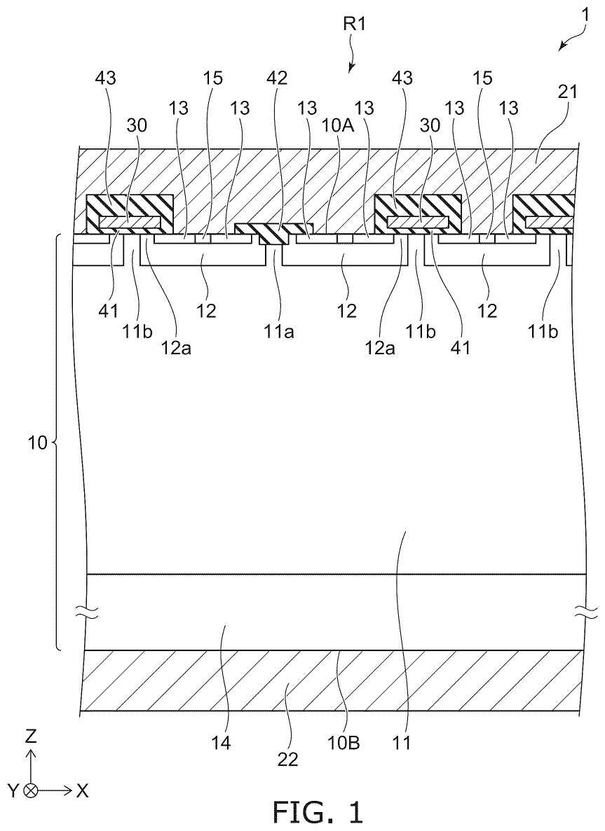

As shown in FIG. 1, a semiconductor device 1 of a first embodiment includes a silicon carbide layer 10. The silicon carbide layer 10 includes a first surface 10A, and a second surface 10B positioned at the side opposite to the first surface 10A in a first direction Z. The first direction Z connects the first surface 10A and the second surface 10B with the shortest distance. Two directions orthogonal to the first direction Z are taken as a second direction X and a third direction Y. The second direction X and the third direction Y are orthogonal to each other.

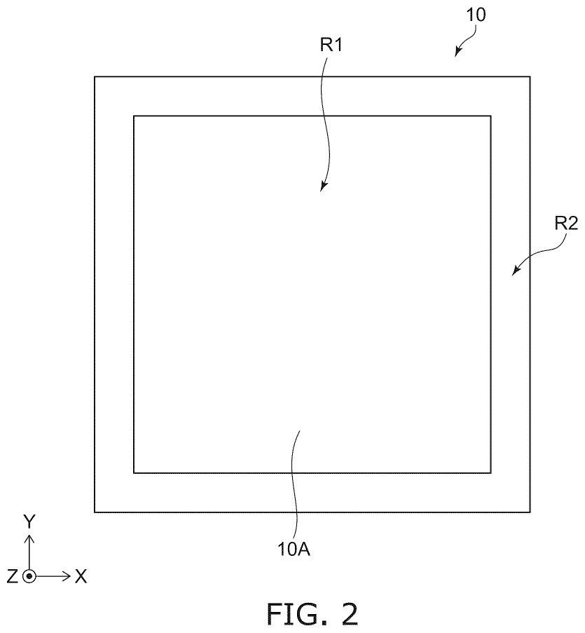

As shown in FIG. 2, the silicon carbide layer 10 includes an element region R1 and a termination region R2. The termination region R2 continuously surrounds the element region R1 when viewed in plan. The area of the element region R1 is greater than the area of the termination region R2.

The silicon carbide layer 10 includes an n-type first semiconductor part 11, and a p-type second semiconductor part 12 located on the first semiconductor part 11 in the first direction Z. The silicon carbide layer 10 further includes an n-type third semiconductor part 13, a p-type fourth semiconductor part 14, and a p-type fifth semiconductor part 15. The third semiconductor part 13 and the fifth semiconductor part 15 are located at a surface of the second semiconductor part 12. The fourth semiconductor part 14 is a SiC substrate; and the first semiconductor part 11 is epitaxially grown on the SiC substrate. The n-type impurity concentration of the third semiconductor part 13 is greater than the n-type impurity concentration of the first semiconductor part 11. The p-type impurity concentration of the fourth semiconductor part 14 and the p-type impurity concentration of the fifth semiconductor part 15 are greater than the p-type impurity concentration of the second semiconductor part 12.

FIG. 1 is a cross-sectional view of the element region R1. At least the first semiconductor part 11 and the fourth semiconductor part 14 are provided continuously in the element region R1 and the termination region R2.

The semiconductor device 1 further includes an upper electrode 21 located on the first surface 10A, and a lower electrode 22 located in the second surface 10B. The lower electrode 22 contacts the lower surface of the fourth semiconductor part 14 and is electrically connected with the fourth semiconductor part 14. The upper electrode 21 contacts the third semiconductor part 13 and is electrically connected with the third semiconductor part 13. The upper electrode 21 contacts the fifth semiconductor part 15; and the second semiconductor part 12 is electrically connected with the upper electrode 21 via the fifth semiconductor part 15.

The semiconductor device 1 of the first embodiment is a bipolar element and has, for example, an IGBT (Insulated Gate Bipolar Transistor) structure. The lower electrode 22 is a collector electrode; the fourth semiconductor part 14 is a collector layer; the first semiconductor part 11 is a drift layer; the second semiconductor part 12 is a base layer; the third semiconductor part 13 is an emitter layer; the upper electrode 21 is an emitter electrode; and the fifth semiconductor part 15 is a base contact layer.

The first semiconductor part 11 of the element region R1 contacts the bottom surface of the second semiconductor part 12 in the first direction Z. The first semiconductor part 11 of the element region R1 is positioned at the first surface 10A side and includes a first portion 11a that is adjacent to the side surface of the second semiconductor part 12 in the second direction X. The first semiconductor part 11 of the element region R1 also includes a second portion 11b that is positioned at the first surface 10A side and is adjacent to the side surface of the second semiconductor part 12 in the second direction X.

The semiconductor device 1 further includes a gate electrode 30. A planar-gate structure is shown in the example shown in FIG. 1. The gate electrode 30 is located on the first surface 10A of the element region R1 of the silicon carbide layer 10. The second semiconductor part 12 includes a portion 12a positioned between the second portion 11b and the third semiconductor part 13 in the second direction X. The gate electrode 30 faces at least the portion 12a of the second semiconductor part 12. The gate electrode 30 also is positioned on the second portion 11b. The semiconductor device 1 is not limited to a planar-gate structure and may have a trench-gate structure.

The semiconductor device 1 further includes a first insulating film 41 located between the gate electrode 30 and the silicon carbide layer 10. The first insulating film 41 is located between the gate electrode 30 and the portion 12a of the second semiconductor part 12 and between the second portion 11b and the gate electrode 30. For example, a silicon oxide film can be used as the first insulating film 41.

The semiconductor device 1 includes a second insulating film 42 located on the first portion 11a of the first semiconductor part 11 in the element region R1. The thickness in the first direction Z of the second insulating film 42 is greater than the thickness in the first direction Z of the first insulating film 41. A portion of the second insulating film 42 is located on the third semiconductor part 13 and on the second semiconductor part 12 adjacent to the first portion 11a. For example, a silicon oxide film can be used as the second insulating film 42.

The semiconductor device 1 further includes an inter-layer insulating film 43 located between the gate electrode 30 and the upper electrode 21. For example, a silicon oxide film can be used as the inter-layer insulating film 43.

In the on-operation of the semiconductor device 1, a potential that is not less than a threshold is applied to the gate electrode 30; and an inversion layer (an n-type channel) is formed in the portion 12a of the second semiconductor part 12 facing the gate electrode 30. A lower potential than that of the lower electrode 22 is applied to the upper electrode 21; and a higher potential than that of the upper electrode 21 is applied to the lower electrode 22. In this state, a current flows between the lower electrode 22 and the upper electrode 21 in the element region R1 via the fourth semiconductor part 14, the second portion 11b of the first semiconductor part 11, the n-type channel, and the third semiconductor part 13.

According to the embodiment, by providing the first portion 11a in the first semiconductor part 11 of the element region R1, carbon vacancies can be reduced by diffusing carbon inside the first semiconductor part 11 of the element region R1 via the first portion 11a as described below. As a result, recombination of holes and electrons in carbon vacancies in a bipolar operation when the semiconductor device 1 is in the on-state can be reduced, and degradation of the operating characteristics of the semiconductor device 1 can be suppressed.

Carbon diffuses below the first portion 11a from the first portion 11a, and further diffuses through the first semiconductor part 11 in the second and third directions X and Y. Accordingly, the carbon density inside the first semiconductor part 11 below the first portion 11a is greater than the carbon density inside the first semiconductor part 11 below the gate electrode 30 (below the second portion 11b). Also, the carbon density inside the first semiconductor part 11 at the first surface 10A side is greater than the carbon density inside the first semiconductor part 11 at the second surface 10B side.

When the potential of the gate electrode 30 drops below the threshold, the n-type channel is cut off, and the semiconductor device 1 is switched to the off-state. In the off-state, a depletion layer spreads through the first semiconductor part 11 from the p-n junction between the n-type first semiconductor part 11 and the p-type second semiconductor part 12; and the breakdown voltage of the semiconductor device 1 is maintained. The second insulating film 42 is located between the first portion 11a and the upper electrode 21, and so leakage current via the first portion 11a can be suppressed, and the breakdown voltage can be maintained. It is favorable for the thickness of the first insulating film 41, which functions as a gate insulating film, to be several tens of nm; and it is favorable for the thickness of the second insulating film 42 to be not less than 100 nm to maintain the breakdown voltage.

Multiple first portions 11a can be located in the element region R1. The planar pattern of the first portion 11a can be, for example, a concentric circular configuration, a stripe configuration, a lattice shape, a dot configuration, etc.

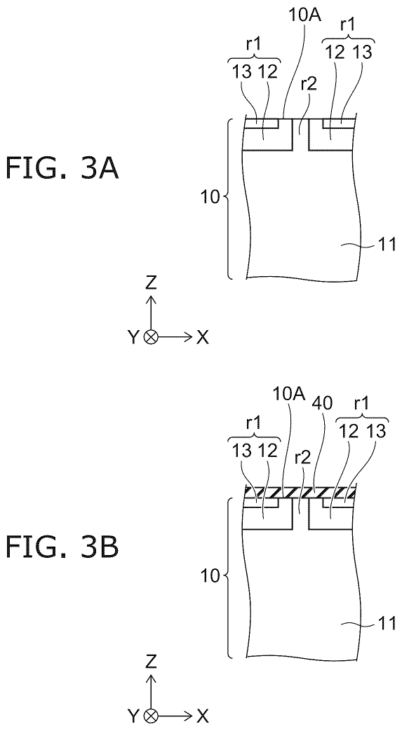

A method for manufacturing the semiconductor device of the first embodiment will now be described with reference to FIGS. 3A to 5B. The cross sections shown in FIGS. 3A to 5B correspond to the portion of the cross section shown in FIG. 1 at which the first portion 11a of the first semiconductor part 11 will be formed.

As shown in FIG. 3A, a first region r1 into which impurities are implanted and a second region r2 into which an impurity is not implanted are formed in the upper portion of the silicon carbide layer 10. The first region r1 is a region into which the impurities are implanted by ion implantation. The first region r1 includes the p-type second semiconductor part 12 and the n-type third semiconductor part 13. After implanting a p-type impurity into the upper portion of the n-type first semiconductor part 11 from the first surface 10A, an n-type impurity is implanted into the upper portion of the n-type first semiconductor part 11. For example, Al (aluminum), B (boron), or Ga (gallium) can be used as the p-type impurity; and N (nitrogen) or P (phosphorus) can be used as the n-type impurity. The impurities are not implanted into the second region r2. The second region r2 is a portion of the first semiconductor part 11. The second region r2 is adjacent to the first region r1 in the second direction X. The first surface 10A of the silicon carbide layer 10 includes the upper surface of the first region r1 and the upper surface of the second region r2. A first heat treatment process is performed after the ion implantation described above. The first heat treatment process activates the first region r1 into which the impurities were implanted. The temperature of the first heat treatment process is, for example, not less than 1,600° C. The high-temperature heat treatment of the first heat treatment process may cause vacancies due to desorption of carbon (C) of the silicon carbide layer 10. According to the embodiment, a second heat treatment process is performed after the first heat treatment process to fill the vacancies occurring in the first heat treatment process with carbon.

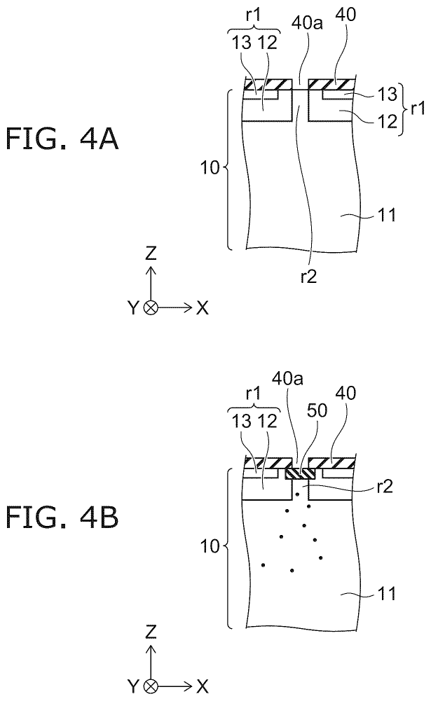

It is favorable to cover the upper surface of the first region r1 with a protective film after the first heat treatment process and before the second heat treatment process. As shown in FIG. 3B, the protective film 40 is formed to cover the entire surface of the first surface 10A of the silicon carbide layer 10 including the upper surface of the first region r1 and the upper surface of the second region r2, and then an opening 40a is formed in the protective film 40 as shown in FIG. 4A. The upper surface of the second region r2 is exposed from under the protective film 40 in the opening 40a. The upper surface of the first region r1 is covered with the protective film 40. For example, a silicon nitride film can be used as the protective film 40.

In the second heat treatment process, the second region r2 is thermally oxidized at a lower temperature than the first heat treatment process. In the second heat treatment process, heat treatment is performed in an atmosphere including oxygen at, for example, a temperature of about 1,300° C. As a result, a thermal oxidation reaction proceeds from the upper surface of the second region r2 exposed in the opening 40a; and a portion (the upper portion) of the second region r2 is converted into a thermally oxidized portion 50 shown in FIG. 4B. The upper surface of the first region r1 is not thermally oxidized because the upper surface of the first region r1 is covered with the protective film 40.

Although the upper surface of the region of the second semiconductor part 12 adjacent to the second region r2 is covered with the protective film 40, there are also cases where the thermal oxidation proceeds in the lateral direction (the second direction X), thereby forming the thermally oxidized portion 50 in the region of the second semiconductor part 12 adjacent to the second region r2.

In the second heat treatment process described above, the carbon in the silicon carbide layer 10 that bonds with oxygen desorbs as CO or CO₂ gas; and the carbon that does not bond with oxygen thermally diffuses from the second region r2 downward, in the second direction X, and in the third direction Y through the silicon carbide layer 10 as schematically illustrated by black circles in FIG. 4B. As a result, the vacancies that occurred in the first heat treatment process can be filled with carbon.

The second region r2 is a region into which an impurity is not ion-implanted; and there are no defects due to ion implantation. Accordingly, carbon can diffuse from the second region r2 into the silicon carbide layer 10 without being obstructed by defects due to ion implantation.

A comparative example may be considered in which carbon is ion-implanted through the first surface 10A of the silicon carbide layer 10 to fill vacancies after the first heat treatment process. However, in such a case, defects due to the ion implantation of carbon may occur at the p-n junction interface between the second semiconductor part 12 and the first semiconductor part 11 and cause a leakage current.

According to the embodiment, defects due to ion implantation of carbon do not occur because carbon is diffused by thermal oxidation treatment.

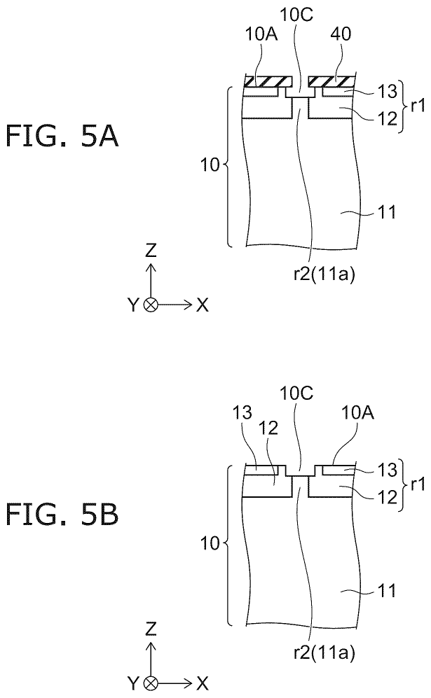

The thermally oxidized portion 50 is removed after the second heat treatment process. For example, the thermally oxidized portion 50 can be removed using hydrofluoric acid, diluted hydrofluoric acid, buffered hydrofluoric acid, etc. As a result, a recess 10C is formed above the second region r2 as shown in FIG. 5A. The second region r2 under the recess 10C becomes the first portion 11a of the first semiconductor part 11 described above. Subsequently, the protective film 40 is removed. For example, the protective film 40 can be removed using high-temperature phosphoric acid. As a result, the upper surface of the first region r1, the upper surface of the second region r2, and the recess 10C are exposed as shown in FIG. 5B.

After removing the protective film 40, the second insulating film 42 shown in FIG. 1 is formed in the recess 10C. For example, the second insulating film 42 can be formed by CVD (Chemical Vapor Deposition) or PVD (Physical Vapor Deposition). The second insulating film 42 is located at least on the first portion 11a of the first semiconductor part 11.

In the case where the protective film 40 is removed using conditions that do not remove the thermally oxidized portion 50 when removing the protective film 40, the thermally oxidized portion 50 may remain as the second insulating film 42 without being removed.

### Second Embodiment

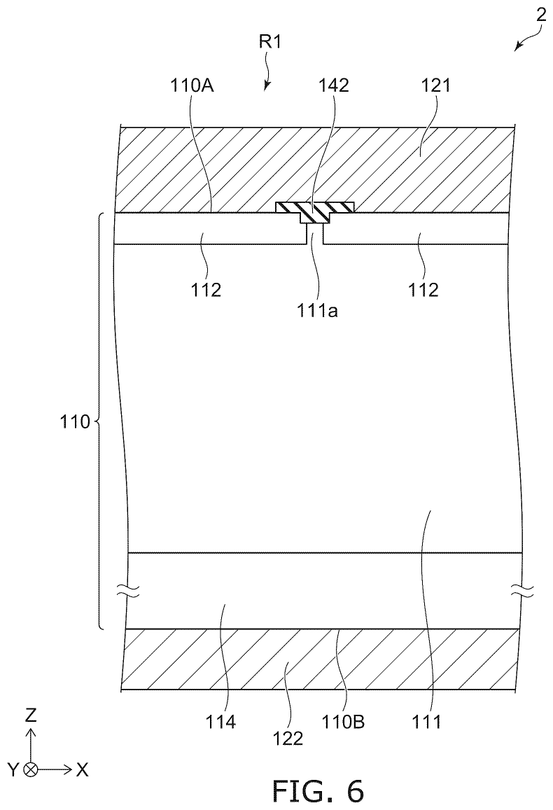

FIG. 6 is a schematic cross-sectional view of a semiconductor device 2 of a second embodiment.

The semiconductor device 2 of the second embodiment includes a silicon carbide layer 110. The silicon carbide layer 110 includes a first surface 110A, and a second surface 110B positioned at the side opposite to the first surface 110A in the first direction Z. Similarly to the first embodiment, the silicon carbide layer 110 of the second embodiment also includes an element region and a termination region. FIG. 6 is a cross-sectional view of the element region R1.

The silicon carbide layer 110 includes an n-type first semiconductor part 111, and a p-type second semiconductor part 112 located on the first semiconductor part 111 in the first direction Z. The silicon carbide layer 110 further includes an n-type third semiconductor part 114. At least the first semiconductor part 111 and the third semiconductor part 114 are provided continuously in the element region and the termination region.

The third semiconductor part 114 is a SiC substrate; and the first semiconductor part 111 is epitaxially grown on the SiC substrate. The n-type impurity concentration of the third semiconductor part 114 is greater than the n-type impurity concentration of the first semiconductor part 111.

The semiconductor device 2 further includes an upper electrode 121 located on the first surface 110A, and a lower electrode 122 located at the second surface 110B. The lower electrode 122 contacts the lower surface of the third semiconductor part 114 and is electrically connected with the third semiconductor part 114. The upper electrode 121 contacts the second semiconductor part 112 and is electrically connected with the second semiconductor part 112.

The semiconductor device 2 of the second embodiment also is a bipolar element, and has, for example, a P-I-N diode structure. The upper electrode 121 is an anode electrode; the second semiconductor part 112 is an anode layer; the first semiconductor part 111 is a drift layer; the third semiconductor part 114 is a cathode layer; and the lower electrode 122 is a cathode electrode.

The first semiconductor part 111 of the element region R1 contacts the bottom surface of the second semiconductor part 112 in the first direction Z. The first semiconductor part 111 of the element region R1 includes a first portion 111a that is positioned at the first surface 110A side and is adjacent to a side surface of the second semiconductor part 112 in the second direction X.

The semiconductor device 2 includes an insulating film 142 located on the first portion 111a of the first semiconductor part 111 in the element region R1. A portion of the insulating film 142 is located on a portion of the second semiconductor part 112 adjacent to the first portion 111a. For example, a silicon oxide film can be used as the insulating film 142.

In the on-operation of the semiconductor device 2, a higher potential than that of the lower electrode 122 is applied to the upper electrode 121; and a lower potential than that of the upper electrode 121 is applied to the lower electrode 122. In this state, a current flows between the upper electrode 121 and the lower electrode 122 in the element region R1 via the second semiconductor part 112, the first semiconductor part 111, and the third semiconductor part 114.

Similarly to the first embodiment above, a method for manufacturing the semiconductor device 2 of the second embodiment includes a process of forming, in the upper portion of the silicon carbide layer 110, the first region (a region at which the second semiconductor part 112 is to be located) into which an impurity is implanted and a second region (a region at which the first portion 111a is to be located) into which an impurity is not implanted, a first heat treatment process of activating the first region, and a second heat treatment process of thermally oxidizing the second region after the first heat treatment process at a lower temperature than the first heat treatment process.

Then, in the second heat treatment process, similarly to the first embodiment, carbon vacancies can be reduced by diffusing carbon inside the first semiconductor part 111 of the element region R1 via the first portion 111a. As a result, recombination of holes and electrons in carbon vacancies in a bipolar operation when the semiconductor device 2 is in the on-state can be reduced, and degradation of the operating characteristics of the semiconductor device 2 can be suppressed.

Carbon diffuses below the first portion 111a from the first portion 111a, and further diffuses through the first semiconductor part 111 in the second and third directions X and Y. Accordingly, the carbon density inside the first semiconductor part 111 below the first portion 111a is greater than the carbon density inside the first semiconductor part 111 below the connection portion between the second semiconductor part 112 and the upper electrode 121. Also, the carbon density inside the first semiconductor part 111 at the first surface 110A side is greater than the carbon density inside the first semiconductor part 111 at the second surface 110B side.

When a reverse voltage is applied to the p-n junction between the second semiconductor part 112 and the first semiconductor part 111, a depletion layer spreads from the p-n junction through the first semiconductor part 111; and the breakdown voltage of the semiconductor device 2 is maintained. The insulating film 142 is located between the upper electrode 121 and the first portion 111a of the first semiconductor part 111, and so a leakage current via the first portion 111a can be suppressed, and the breakdown voltage can be maintained. It is favorable for the thickness of the insulating film 142 to be not less than 100 nm to maintain the breakdown voltage.

Multiple first portions 111a can be provided in the element region R1. The planar pattern of the first portion 111a can be, for example, a concentric circular configuration, a stripe configuration, a lattice shape, a dot configuration, etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a silicon carbide layer including
an element region,
a termination region surrounding the element region,
a first semiconductor part including a first portion in the element region, the first semiconductor part being of a first conductivity type, and
a second semiconductor part located on the first semiconductor part in a first direction, the second semiconductor part being adjacent to the first portion in a second direction orthogonal to the first direction;
a gate electrode facing the second semiconductor part of the element region;
a first insulating film located between the gate electrode and the silicon carbide layer; and
a second insulating film located on the first portion of the first semiconductor part, the second insulating film being thicker than the first insulating film.

2. The device according to claim 1, wherein
a carbon density inside the first semiconductor part below the first portion is greater than a carbon density inside the first semiconductor part below the gate electrode.

3. The device according to claim 1, wherein
a thickness of the second insulating film is not less than 100 nm.

4. The device according to claim 1, further comprising:
an upper electrode; and
a lower electrode,
the silicon carbide layer further including
a third semiconductor part located at a surface of the second semiconductor part, the third semiconductor part contacting the upper electrode, the third semiconductor part being of the first conductivity type, and
a fourth semiconductor part located between the lower electrode and the first semiconductor part, the fourth semiconductor part contacting the lower electrode, the fourth semiconductor part being of a second conductivity type.

5. The device according to claim 4, wherein
the second insulating film also is located on:
the second semiconductor part adjacent to the first portion; and
the third semiconductor part.

6. The device according to claim 4, wherein
the silicon carbide layer includes:
a first surface positioned at the upper electrode side; and
a second surface positioned at the lower electrode side, and
a carbon density inside the first semiconductor part at the first surface side is greater than a carbon density inside the first semiconductor part at the second surface side.

7. A semiconductor device, comprising:
a silicon carbide layer including
an element region,
a termination region surrounding the element region,
a first semiconductor part including a first portion in the element region, the first semiconductor part being of a first conductivity type, and
a second semiconductor part located on the first semiconductor part in a first direction, the second semiconductor part being adjacent to the first portion in a second direction orthogonal to the first direction;
an upper electrode located on the second semiconductor part of the element region, the upper electrode being electrically connected with the second semiconductor part; and
an insulating film located on the first portion of the first semiconductor part.

8. The device according to claim 7, wherein
a carbon density inside the first semiconductor part below the first portion is greater than a carbon density inside the first semiconductor part below a connection portion between the second semiconductor part and the upper electrode.

9. The device according to claim 7, wherein
a thickness of the second insulating film is not less than 100 nm.

10. The device according to claim 7, further comprising:
an upper electrode contacting the second semiconductor part; and
a lower electrode,
the silicon carbide layer further including
a third semiconductor part located between the lower electrode and the first semiconductor part, the third semiconductor part contacting the lower electrode, the third semiconductor part being of a first conductivity type.

11. The device according to claim 7, wherein
the insulating film also is located on a portion of the second semiconductor part adjacent to the first portion.

12. A method for manufacturing a semiconductor device, the method comprising:
forming a first region and a second region in an upper portion of a silicon carbide layer by implanting an impurity into the first region and by not implanting an impurity into the second region;
a first heat treatment process of activating the first region; and
a second heat treatment process of thermally oxidizing the second region after the first heat treatment process at a lower temperature than the first heat treatment process.

13. The method according to claim 12, further comprising:
covering an upper surface of the first region with a protective film before the second heat treatment process.

14. The method according to claim 12, wherein
a temperature of the first heat treatment process is not less than 1,600° C.

15. The method according to claim 12, wherein
the second heat treatment process is performed in an atmosphere including oxygen.
